(19) United States
(12) Patent Application Publication
(10) Pub. No.: US 2012/0126256 A1
(43) Pub. Date: May 24, 2012

(54) LED PACKAGE

(75) Inventors: Tetsuro Komatsu, Fukuoka-ken (JP); Naoya Ushiyama, Fukuoka-ken (JP)

(73) Assignee: KABUSHIKI KAISHA TOSHIBA, Tokyo (JP)

(21) Appl. No.: 13/053,522

(22) Filed: Mar. 22, 2011

(30) Foreign Application Priority Data
Nov. 19, 2010 (JP) 2010-259081

(51) Int. Cl. H01L 27/15; H01L 33/52

(52) U.S. Cl. 257/88; 257/99; 257/E33.059; 257/E27.12

(57) ABSTRACT

According to one embodiment, an LED package includes a first and a second lead frame separated from each other, an LED chip, a wire and a resin body. The LED chip is provided above the first and second lead frames, and has a pair of terminals provided on an upper surface of the LED chip. One of the terminals is connected to the first lead frame and one other terminal is connected to the second lead frame. The wire is drawn out from the one terminal horizontally to connect the one terminal to the first lead frame. The resin body covers the LED chip and the wire, an upper surface, a part of a lower surface and a part of an end surface of each of the first and second lead frames to expose a remaining part of the lower surface and a remaining part of the lower surface.

### CROSS-REFERENCE TO RELATED APPLICATIONS

This application is based upon and claims the benefit of priority from the prior Japanese Patent Application No. 2010-259081, filed on Nov. 19, 2010; the entire contents of which are incorporated herein by reference.

### FIELD

Embodiments described herein relate generally to a lead package.

### BACKGROUND

Conventionally, in an LED package that mounts LED chips, a bowl-shaped envelope formed of white resin has been provided, the LED chips have been mounted on a bottom surface of the envelope, and transparent resin has been encapsulated inside the envelope to embed the LED chips for the purpose of controlling a light distribution characteristic to increase light extraction efficiency from the LED package. Additionally, the envelopes have been formed of polyamide series thermoplastic resin in many cases. However, in recent years, higher durability of the LED packages has been requested along with an expanding application range of the LED packages

### BRIEF DESCRIPTION OF THE DRAWINGS

FIG. 1 is a perspective view illustrating an LED package according to a first embodiment;

FIG. 2A is a cross-sectional view illustrating the LED package according to the first embodiment, and FIG. 2B is a plan view illustrating lead frames and a transparent resin body;

FIG. 3 is a flowchart illustrating a method for manufacturing the LED package according to the first embodiment;

FIGS. 4A to 6B are process cross-sectional views illustrating the method for manufacturing the LED package according to the first embodiment;

FIG. 7A is a plan view illustrating a lead frame sheet of the first embodiment, and FIG. 7B is a partial enlarged view illustrating element regions of the lead frame sheet;

FIGS. 8A to 8C are process cross-sectional views illustrating a wire bonding method of the first embodiment;

FIGS. 9A to 9D are schematic views illustrating the effect of the looped shape of the wires on wire deformation volume;

FIGS. 10A 10B are optical microscope photographs showing a sample in the test example 1;

FIGS. 11A to 11H are process cross-sectional views illustrating a method for forming the lead frame in a variation of the first embodiment;

FIG. 12 is a plan view illustrating an LED package according to a second embodiment;

FIG. 13 is a perspective view illustrating an LED package according to a third embodiment;

FIG. 14A is a plan view illustrating lead frames, LED chips and wires of the LED package according to the third embodiment, FIG. 14B is a bottom view illustrating the LED package and the FIG. 14C is a cross-sectional view illustrating the LED package;

FIG. 15 is a plan view illustrating the LED chips and wires of the LED package according to the third embodiment;

FIGS. 16A to 16D are photographs illustrating samples in the test example 2; and

FIG. 17 is a graph illustrating the effect of the wire looped shape on durability, and its horizontal axis represents the number of cycles and its vertical axis represents a percent defective.

### DETAILED DESCRIPTION

In general, according to one embodiment, an LED package includes a first and a second lead frame separated from each other, an LED chip, a wire and a resin body. The LED chip is provided above the first and second lead frames, the LED chip has a pair of terminals provided on an upper surface of the LED chip, one of the terminals is connected to the first lead frame and one other terminal is connected to the second lead frame. The wire is drawn out from the one terminal in a horizontal direction to connect the one terminal to the first lead frame. The resin body covers the LED chip and the wire, an upper surface, a part of a lower surface and a part of an end surface of each of the first and second lead frames to expose a remaining part of the lower surface and a remaining part of the lower surface. An outer shape of the resin body forms an outer shape of the LED package.

Various embodiments will be described hereinafter with reference to the accompanying drawings.

First, a first embodiment will be described.

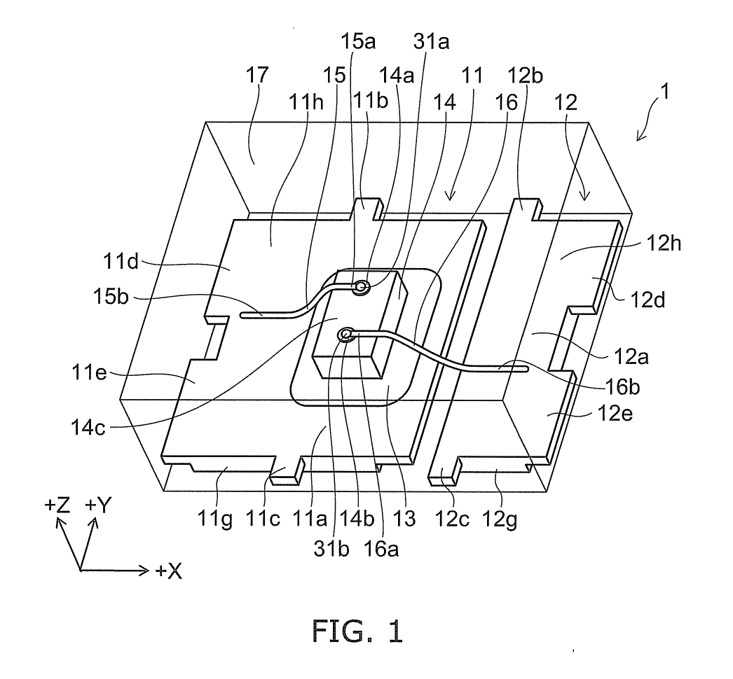

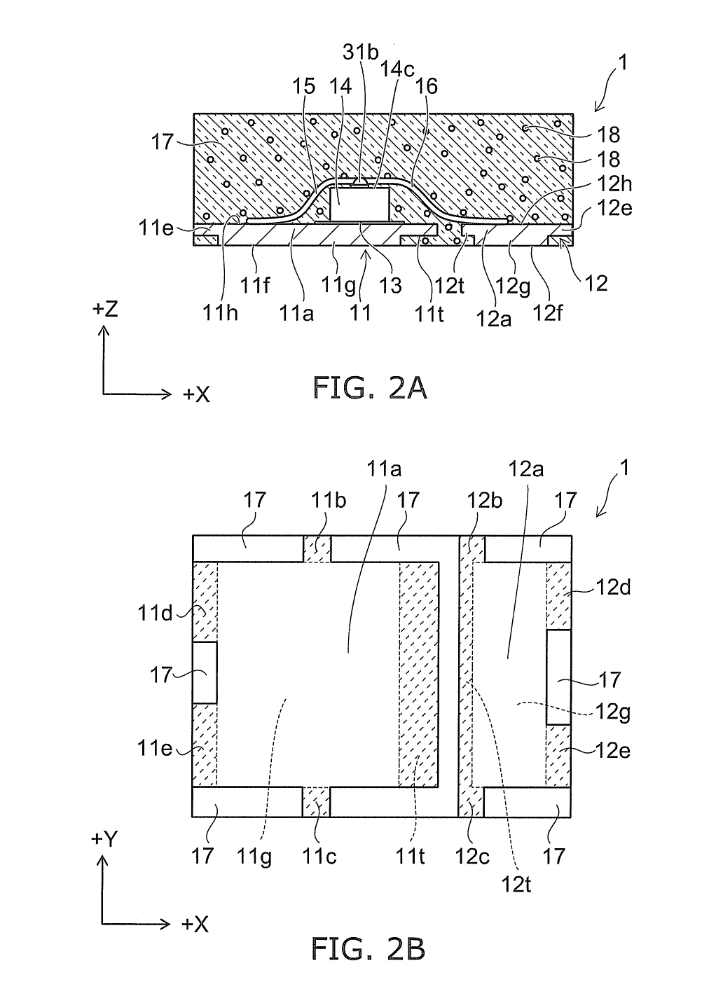

FIG. 1 is a perspective view illustrating an LED package according to the embodiment, FIG. 2A is a cross-sectional view illustrating the LED package according to the embodiment and FIG. 2B is a plan view illustrating lead frames and a transparent resin body.

As shown in FIG. 1 and FIG. 2, the LED package 1 according to the embodiment includes a pair of lead frames 11 and 12. The lead frames 11 and 12 each are shaped like a flat plate and are disposed on a same plane separately from each other. The lead frames 11 and 12 are made of a same conductive material and configured by, for example, forming a silver plating layer on an upper surface and a lower surface of a copper plate. The silver plating layer is not formed on end surfaces of the lead frames 11 and 12, so that the copper plate is exposed thereon.

In the specification, for convenience of description, an XYZ rectangular coordinate system is introduced. A direction from the lead frame 11 toward the lead frame 12 among directions parallel to the upper surfaces of the lead frames 11 and 12 is defined as a +X direction, an upward direction toward a below-mentioned LED chip 14 when viewed from the lead frames among directions perpendicular to the upper surfaces of the lead frames 11 and 12 is defined as a +Z direction and one of directions perpendicular to both the +X direction and the +Z direction is defined as a +Y direction. Directions opposite to the +X direction, the +Y direction and the +Z direction are defined as a −X direction, a −Y direction and a −Z direction, respectively. Further, for example, the “+X direction” and the “−X direction” are also collectively referred to as merely “X direction”.

The lead frame 11 is provided with a base 11a that is rectangular when viewed from the Z direction and four extending portions 11b, 11c, 11d and 11e extend from the base 11a. The extending portion 11b extends from a center part in the X direction of an edge of the base 11a on the +Y direction side toward the +Y direction. The extending portion 11c extends from a center part in the X direction of an edge of the base 11a on the −Y direction side toward the −Y direction. Positions of the extending portion 11b and the 11c in the X direction are the same as each other. The extending portions 11d and 11e extend from both ends of an edge of the base 11a on the −X direction side toward the −X direction. In this manner, the extending portions 11b to 11e extend from three different sides of the base 11a.

The lead frame 12 is shorter than the lead frame 11 in the X direction and the lead frame 12 has the same length as the lead frame 11 in the Y direction. The lead frame 12 is provided with a base 12a that is rectangular when viewed from the Z direction and four extending portions 12b, 12c, 12d and 12e extend from the base 12a. The extending portion 12b extends from an end on the −X direction side of an edge of the base 12a on the +Y direction side toward the +Y direction. The extending portion 12c extends from an end on the −X direction of an edge of the base 12a on the −Y direction side toward the −Y direction. The extending portions 12d and 12e extend from both ends of an edge of the base 12a on the +X direction side toward the +X direction. In this manner, the extending portions 12b to 12e extend from the three different sides of the base 12a. Width of the extending portions 11d and 11e of the lead frame 11 may be the same as or different from width of the extending portions 12d and 12e of the lead frame 12. However, when the width of the extending portions lid and 11e is different from the extending portions 12d and 12e, it is easy to distinguish an anode from a cathode.

A protruding portion 11g is formed at the center portion of the base 11a in the X direction in a lower surface 11f of the lead frame 11. An area of the base 11a where the protruding portion 11g is not formed, that is, an end on the +X direction side, constitutes a thin plate part 11t. The thickness of the thin plate part 11t is equal to that of the extending portions 11b to 11e. For this reason, the thickness of the lead frame 11 has values of two levels and the area of the base 11a where the protruding portion 11g is formed constitutes a relatively thick plate portion. The thin plate portion 11t and the extending portions 11b to 11e of the base 11a constitute a relatively thin plate portion.

Similarly, a protruding portion 12g is formed at the center of the base 12a in the X direction in a lower surface 12f of the lead frame 12. An area of the base 12a where the protruding portion 12g is not formed, that is, both ends in the X direction constitutes a thin plate portion 12t. The thickness of the thin plate portion 12t is equal to that of the extending portions 12b to 12e. Thus, the thickness of the lead frame 12 also has values of two levels and the center portion of the base 12a in the X direction has the protruding portion 12g and thus, constitutes a thick plate portion. Both ends of the base 12a in the X direction and the extending portions 12b to 12e constitute a relatively thin portion. In FIG. 2B, the thin plate portions of the lead frames 11 and 12, that is, each thin plate portion and each extending portion are hatched by broken lines.

The protruding portions 11g and 12g are formed in regions separated from edges of the lead frames 11 and 12, which are opposed to each other, and regions including these edges constitute the thin plate portions 11t and 12t. In other words, Notches extending along the edges of the base 11a and the 12a in the Y direction are formed on lower surfaces of both ends of the bases 11a and 12a in the X direction, respectively. An upper surface 11h of the lead frame 11 and an upper surface 12h of the lead frame 12 are disposed in the same plane, and a lower surface of the protruding portion 11g of the lead frame 11 and a lower surface of the protruding portion 12g of the lead frame 12 are disposed in the same plane. Positions of the extending portions on the upper surfaces in the Z direction match positions on the upper surfaces of the lead frames 11 and 12. Therefore, the extending portions lie in the same XY plane.

A die-mount material 13 is deposited on part of the upper surface 11h of the lead frame 11, which corresponds to the base 11a. In the embodiment, the die-mount material 13 may be conductive or insulative. When the die-mount material 13 is conductive, the die-mount material 13 is formed by silver paste, solder or eutectic solder, for example. When the die-mount material 13 is insulative, the die-mount material 13 is formed by transparent resin paste, for example.

The LED chip 14 is provided on the die-mount material 13. That is, by fixing the LED chip 14 to the lead frame 11 with the die-mount material, the LED chip 14 is mounted on the lead frame 11. For example, the LED chip 14 is formed by laminating a semiconductor layer made of gallium nitride (GaN) or the like on a sapphire substrate, is shaped like a rectangular parallelepiped and has terminals 14a and 14b thereon. By supplying a voltage between the terminal 14a and the terminal 14b, the LED chip 14 emits blue light, for example. One end 15a of a wire 15 is bonded to the terminal 14a of the LED chip 14 and the other end 15b of the wire 15 is bonded to the upper surface 11h of the lead frame 11. Thereby, the terminal 14a is connected to the lead frame 11 via the wire 15. One end 16a of a wire 16 is bonded to the terminal 14b and the other end 16b of the wire 16 is bonded to the upper surface 12h of the lead frame 12. Thereby, the terminal 14b is connected to the lead frame 12 via the wire 16. The wires 15 and 16 are made of metal such as gold or aluminum. Bumps 31a and 31b made of the same material as that of the wires are provided at a connection of the terminal 14a and the wire 15 and a connection of the terminal 14b and the wire 16, respectively.

In the embodiment, the wire 15 is drawn from the terminal 14a in horizontal direction (substantially in the X direction) and is drawn downwards (in the −Z direction) when exceeding an outer edge of the LED chip 14 in the −X direction, and then, is curved so as to be convex downward. Then, when the wire 15 comes to extend substantially in the horizontal direction (in the −X direction), the side surface of the wire 15 comes in contact with the upper surface of the lead frame 11. Similarly, the wire 16 is drawn from the terminal 14b in the horizontal direction (substantially in the +X direction) and is drawn downwards (in the −Z direction) when exceeding the end edge of the LED chip 14 on the +X direction side, and then is curved so as to be convex downward. Then, when the wire 16 comes to extend substantially in the horizontal direction (in the +X direction), the side surface of the wire 16 comes in contact with the upper surface of the lead frame 12. The “horizontal direction” refers to the direction parallel to or substantially parallel to the XY plane. In a scope of the “horizontal direction”, for example, an upward inclination angle with respect to the XY plane is equal to or smaller than 20 degrees and a downward inclination angle is an angle at which the wire is not contact with the LED chip 14. Since the wires are shaped like a loop as described above, the wires 15 and 16 are not disposed above the bumps 31a and 31b.

The LED package 1 is provided with a transparent resin body 17. The transparent resin body 17 is made of transparent resin such as silicone resin. “Transparent” includes translucent. The transparent resin body 17 is shaped like a rectangular parallelepiped and covers the lead frames 11 and 12, the die-mount material 13, the LED chip 14 and the wires 15 and 16. The outer shape of the transparent resin body 17 forms the outer shape of the LED package 1. Part of the lead frame 11 and part of the lead frame 12 are exposed on a lower surface and side surfaces of the transparent resin body 17.

Describing in detail, the lower surface of the protruding portion 11g of the lower surface 11f of the lead frame 11 is exposed on the lower surface of the transparent resin body 17 and front end surfaces of the extending portions 11b to 11e are exposed on a side surface of the transparent resin body 17. The whole upper surface 11h of the lead frame 11, a region of the lower surface 11f other than the protruding portion 11g, a side surface of the protruding portion 11g, an end surface of the base 11a and side surfaces of the extending portions 11b to 11e are covered with the transparent resin body 17. Similarly, a lower surface of the protruding portion 12g of the lead frame 12 is exposed on a lower surface of the transparent resin body 17, front end surfaces of the extending portions 12b to 12e are exposed on the side surface of the transparent resin body 17, and the whole upper surface 12h, a region of the lower surface 12f other than the protruding portion 12g, a side surface of the protruding portion 12g, an end surface of the base 12a and side surfaces of the extending portions 12b to 12e are covered with the transparent resin body 17. In the LED package 1, the lower surfaces of the protruding portions 11g and 12g exposed on the lower surface of the transparent resin body 17 constitute an external electrode pad. As described above, the shape of the transparent resin body 17 when viewed from above is rectangular and the front end surfaces of the above-mentioned plurality of extending portions are exposed on the three different side surfaces of the transparent resin body 17. In this specification, “cover” means both cases where a covering object is and is not in contact with a covered object.

A lot of phosphors 18 are dispersed in the transparent resin body 17. Each of the phosphors 18 is granular, absorbs light emitted from the LED chip 14 and emits light with a longer wavelength. For example, the phosphors 18 absorb part of blue light emitted from the LED chip 14 and emit yellow light. Thereby, the LED package 1 emits the blue light that is emitted from the LED chip 14 and is not absorbed by the phosphors 18 and the yellow light emitted from the phosphors 18, so that emitted light becomes white as a whole. For convenience of illustration, figures other than FIG. 2 do not show the phosphors 18. In FIG. 2, smaller and fewer phosphors 18 than actual are shown.

Silicate-based phosphors that emit yellowish green, yellow or orange light, for example, can be used as such phosphors 18. The silicate-based phosphor can be expressed as a following general formula.

(2-x-y)SrO.x(Baᵤ,Caᵥ)O.(1-a-b-c-d)SiO₂.aP₂O₅bAl₂O₃cB₂O₃dGeO₂: yEu²⁺

Where, 0<x, 0.005<y<0.5, x+y ≦1.6, 0≦a, b, c, d<0.5, 0<u, 0<v, u+v=1.

YAG-based phosphors can be used as yellow phosphors. The YAG-based phosphors can be expressed as a following general formula.

(RE₁₋ₓSmₓ)₃(Al_{y}Ga_{1-y})₅O₁₂: Ce

Where, 0≦x<1, 0≦y≦1, RE is at least one type of element selected from Y and Gd.

Mixtures of sialon-based red phosphors and green phosphors can be used as the phosphors 18. That is, the phosphors may be green phosphors that absorb blue light emitted from the LED chip 14 and emit green light, or may be red phosphors that absorb blue light and emit red light.

The sialon-based red phosphors can be expressed as a following general formula.

(M₁₋ₓ,Rₓ)ₐ₁AlSi_{b1}O_{c1}N_{d1}

Where, M is at least one type of metal element except for Si and Al and is desirably at least one of Ca and Sr. R is an emission center element and is desirably Eu. x, a1, b1, c1, d1 are 0<x≦1, 0.6<a1<0.95, 2<b1<3.9, 0.25<c1<0.45, 4<d1<5.7.

An example of such sialon-based red phosphor is as follows.

Sr₂Si₇Al₇ON₁₃: Eu^{2 +}

The sialon-based red phosphor can be expressed as a following general formula, for example.

(M₁₋ₓ,Rₓ)ₐ₂AlSi_{b2}O_{c2}N_{d2}

Where, M is at least one type of metal element except for Si and Al and is desirably at least one of Ca and Sr. R is an emission center element and is desirably Eu. x, a2, b2, c2, d2 are 0<x≦1, 0.93<a2<1.3, 4.0<b2<5.8, 0.6<c2<1, 6<d2<11.

An example of such sialon-based green phosphors is as follows:

Sr₃Si₁₃Al₃O₂N₂₁: Eu²⁺

Next, a method for manufacturing the LED package according to the embodiment will be described.

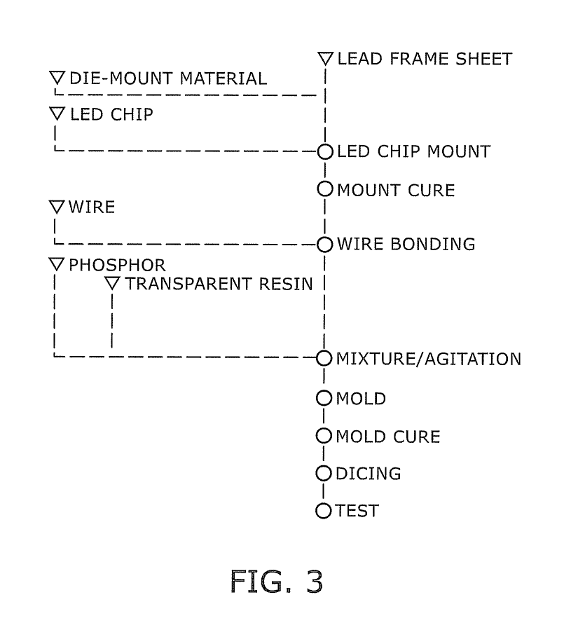

FIG. 3 is a flowchart illustrating the method for manufacturing f the LED package according to the embodiment,

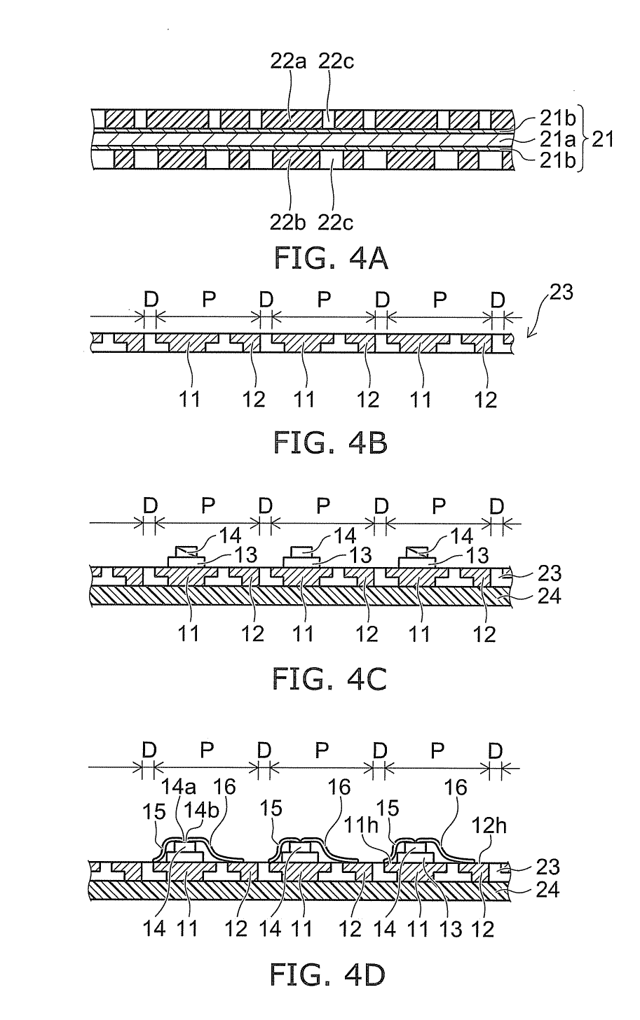

FIGS. 4A to 4D, FIGS. 5A to 5C, FIGS. 6A and 6B are process cross-sectional views illustrating the method for manufacturing the LED package according to the embodiment,

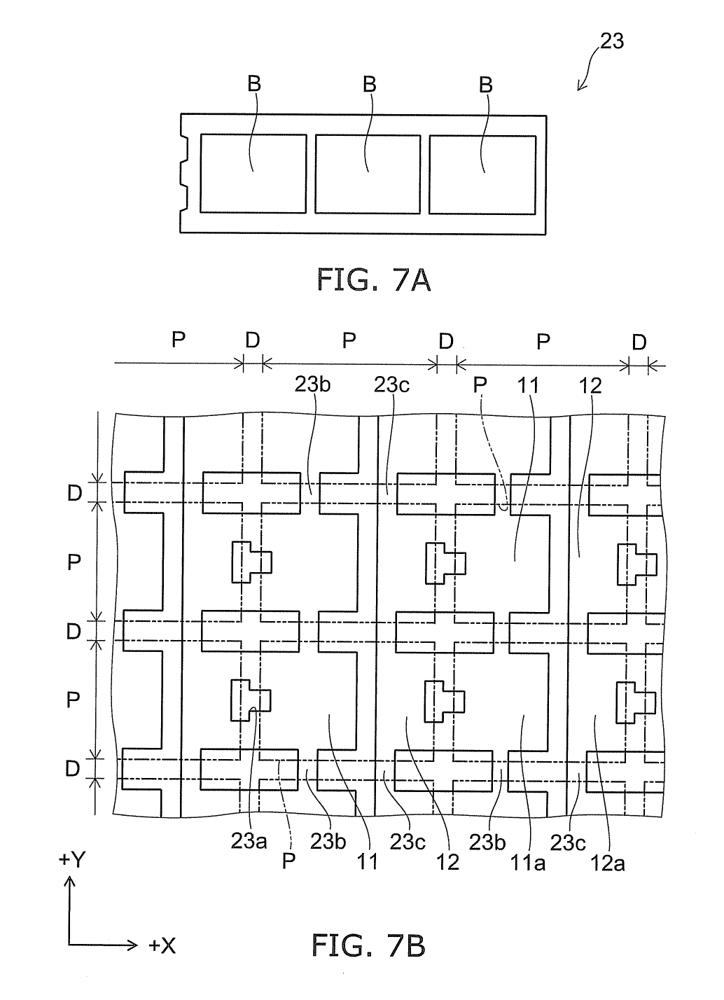

FIG. 7A is a plan view illustrating a lead frame sheet of the embodiment and FIG. 7B is a partial enlarged view illustrating element regions of the lead frame sheet, and

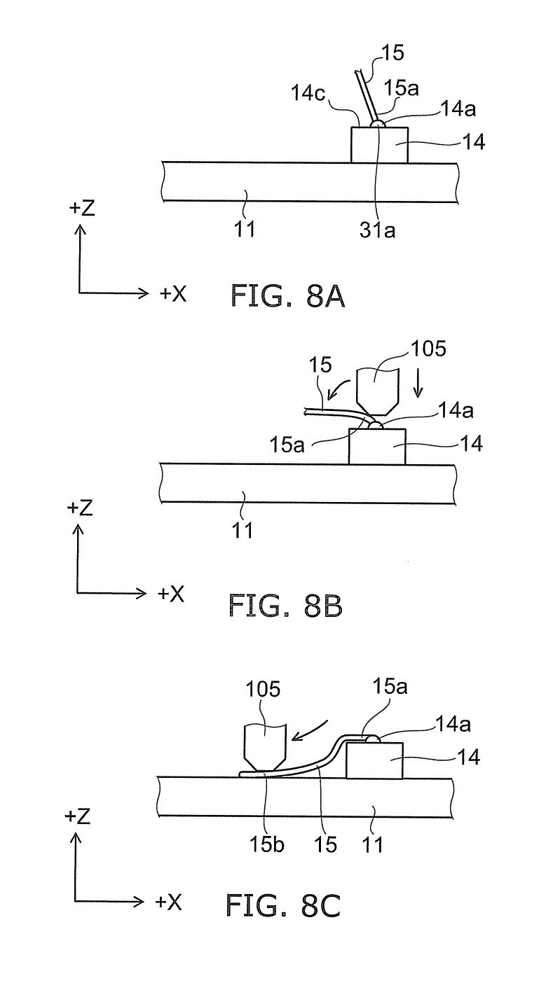

FIGS. 8A to 8C are process cross-sectional views illustrating a wire bonding method of the embodiment.

First, as shown in FIG. 4A, a conductive sheet 21 made of a conductive material is prepared. The conductive sheet 21 is formed by, for example, applying a silver plating layer 21b on each of an upper surface and a lower surface of a strip-like copper plate 21a. Next, masks 22a and 22b are formed on an upper surface and a lower surface of the conductive sheet 21. An opening 22c is selectively formed on each of the masks 22a and 22b. For example, the masks 22a and 22b can be formed by a printing method.

Next, the conductive sheet 21 is wet-etched by immersing the conductive sheet 21 to which the masks 22a and 22b are adhered into an etching liquid. Thereby, a part located in the opening 22c in the conductive sheet 21 is etched and selectively removed. At this time, an etching amount is controlled for example, by adjusting immersion time to stop etching before etching from the upper surface and lower surface sides of the conductive sheet 21 independently penetrate the conductive sheet 21. In this manner, half-etching is performed from the upper surface and lower surface sides. However, the portion etched from both of the upper surface and lower surface sides penetrates the conductive sheet 21. After that, the masks 22a and 22b are removed.

Thereby, as shown in FIG. 3 and FIG. 4B, the copper plate 21a and the silver plating layer 21b are selectively removed from the conductive sheet 21 to form the lead frame sheet 23. For convenience of illustration, in FIG. 4B and subsequent figures, the copper plate 21a and the silver plating layer 21b are integrally shown as the lead frame sheet 23 without being distinguished from each other. As shown in FIG. 7A, in the lead frame sheet 23, for example, three blocks B are set and for example, about 1000 element regions P are set in each block B. As shown in FIG. 7B, the element regions P are arranged in a matrix and a grid-like dicing region D is formed between the element regions P. A basic pattern including the distinct lead frames 11 and 12 is formed in each element region P. In the dicing region D, the conductive material forming the conductive sheet 21 remains so as to connect adjacent element regions P to each other.

That is, although the lead frame 11 is separated from the lead frame 12 in the element region P, the lead frame 11 that belongs to a certain element region P is connected to the lead frame 12 that belongs to an adjacent element region P in the −X direction when viewed from the former element region P and a anastatic opening 23a oriented in the +X direction is formed between the frames. The lead frames 11 that belong to element regions P that are adjacent to each other in the Y direction are coupled to each other via a bridge 23b. Similarly, the lead frames 12 that belong to element regions P that are adjacent to each other in the Y direction are coupled to each other via a bridge 23c. As a result, four conductive members extend from the bases 11a and 12a of the lead frames 11 and 12 in three directions. Further, by performing half-etching from the lower surface of the lead frame sheet 23, the protruding portions 11g and 12g are formed in the lower surfaces of the lead frames 11 and 12, respectively (refer to FIG. 2).

Next, as shown in FIG. 3 and FIG. 4C, a reinforcing tape 24 made of polyimide, for example, is attached to the lower surface of the lead frame sheet 23. Then, the die-mount material 13 is adhered to the lead frame 11 that belongs to each element region P of the lead frame sheet 23. For example, the paste-like die-mount material 13 is discharged from a discharger onto the lead frame 11 or is transferred onto the lead frame 11 by use of a mechanical means. Next, the LED chip 14 is mounted on the die-mount material 13. Next, heat treatment (mount cure) for sintering the die-mount material 13 is performed. Thereby, in each element region P of the lead frame sheet 23, the LED chip 14 is mounted on the lead frame 11 via the die-mount material 13.

Next, as shown in FIG. 3 and FIG. 4D, by, for example, ultrasonic bonding, one end of the wire 15 is bonded to the terminal 14a of the LED chip 14 and the other end of the wire 15 is bonded to the upper surface of the lead frame 11. One end of the wire 16 is bonded to the terminal 14b of the LED chip 14 and the other end of the wire 16 is bonded to the upper surface 12h of the lead frame 12. Thereby, the terminal 14a is connected to the lead frame 11 via the wire 15 and the terminal 14b is connected to the lead frame 12 via the wire 16.

A method of bonding the wire 15 to the terminal 14a and the lead frame 11 will be described below. A method of bonding the wire 16 is similar to the method of bonding the wire 15.

FIGS. 8A to 8C are process cross-sectional views illustrating the wire bonding method of the embodiment.

First, as shown in FIG. 8A, one end 15a of the wire 15 is bonded to the terminal 14a provided on upper surface 14c of the LED chip 14 to form the bump 31a. Then, the wire 15 is drawn out from the bump 31a obliquely upwards. Next, as shown in FIG. 8B, a connection of the end 15a and the terminal 14a is pressed from above with a jig 105. Thereby, the direction of drawing out the wire 15 from the terminal 14a is inclined so as to get close to the −X direction. Next, as shown in FIG. 8C, the wire 15 drawn out from the connection is drawn downwards (in the −Z direction) to the extent that the wire 15 does not comes in contact with the LED chip 14 and the wire 15 is curved so as to be convex downward. Then, the direction of extending the wire 15 is made close to the −X direction again and the side surface of the wire 15 is bonded to the upper surface of the lead frame 11. In this case, no bump is formed at the bonded part of the wire 15 and the lead frame 11. After that, the wire 15 is cut. Thereby, the wire 15 is connected between the terminal 14a and the lead frame 11.

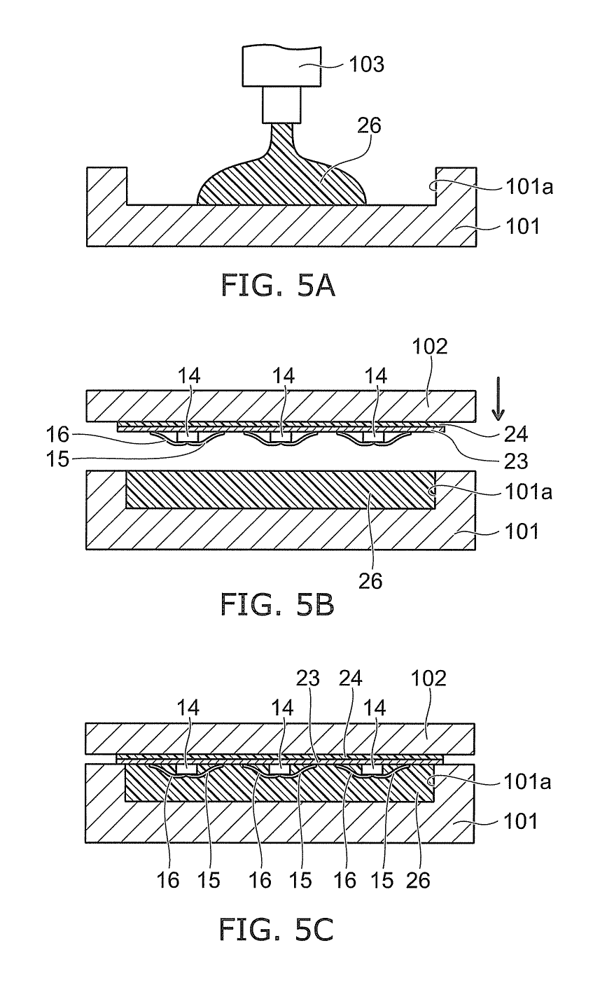

Next, as shown in FIG. 3 and FIG. 5A, a lower mold 101 is prepared. The lower mold 101 and a below-mentioned upper mold 102 constitute a pair of molds and a depression part 101a shaped like a rectangular parallelepiped is formed on an upper surface of the lower mold 101. Meanwhile, by mixing and churning transparent resin such as silicone resin and the phosphors 18 (refer to FIG. 2), a liquid or semiliquid phosphor-containing resin material 26 is prepared. Then, the phosphor-containing resin material 26 is supplied into the depression part 101a of the lower mold 101 by means of a dispenser 103.

Next, as shown in FIG. 3 and FIG. 5B, the lead frame sheet 23 that mounts the above-mentioned LED chip 14 thereon is attached to a lower surface of the upper mold 102 so that the LED chip 14 faces downwards. Then, the upper mold 102 is pressed onto the lower mold 101 to clamp the molds. Thereby, the lead frame sheet 23 is pressed onto the phosphor-containing resin material 26. At this time, the phosphor-containing resin material 26 covers the LED chip 14 and the wires 15 and 16 and also enters into the part of the lead frame sheet 23, which is removed by etching. In this manner, the phosphor-containing resin material 26 is molded. It is preferred that this mold process is performed in a vacuum atmosphere. This can prevent air bubbles generated in the phosphor-containing resin material 26 from adhering to the half-etched part of the lead frame sheet 23.

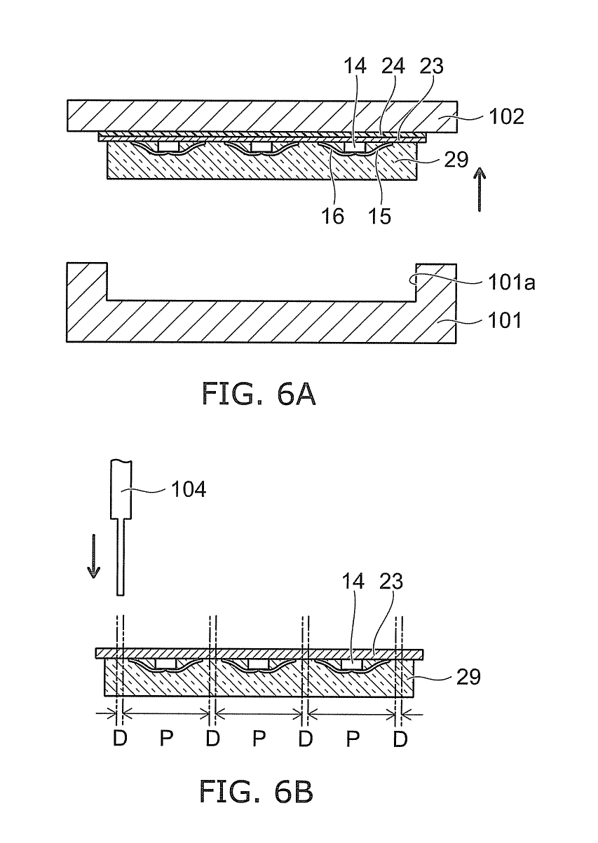

Next, as shown in FIG. 3 and FIG. 5C, heat treatment (mold cure) is performed in the state where the upper surface of the lead frame sheet 23 is pressed onto the phosphor-containing resin material 26 to cure the phosphor-containing resin material 26. After that, as shown in FIG. 6A, the upper mold 102 is detached from the lower mold 101. Thereby, a transparent resin plate 29 that covers the whole upper surface and part of the lower surface of the lead frame sheet 23 and embeds the LED chip 14 and the like therein is formed on the lead frame sheet 23. The phosphors 18 (refer to FIG. 2) are dispersed in the transparent resin plate 29. After that, the reinforcing tape 24 is peeled off from the lead frame sheet 23. Thereby, lower surfaces of the protruding portions 11g and 12g of the lead frames 11 and 12 (refer to FIG. 2) are exposed on the surface of the transparent resin plate 29.

Next, as shown in FIG. 3 and FIG. 6B, a combined body formed of the lead frame sheet 23 and the transparent resin plate 29 is diced from the side of the lead frame sheet 23 by use of a blade 104. That is, it is diced toward the +Z direction. Thereby, parts of the lead frame sheet 23 and the transparent resin plate 29, which are disposed in the dicing region D, are removed. As a result, parts of the lead frame sheet 23 and the transparent resin plate 29, which are disposed in the element region P, are divided into pieces to produce the LED package 1 shown in FIG. 1 and FIG. 2. The combined body formed of the lead frame sheet 23 and the transparent resin plate 29 may be diced from the side of the transparent resin plate 29.

In each LED package 1 after dicing, the lead frames 11 and 12 are separated from the lead frame sheet 23. The transparent resin plate 29 is also separated to form the transparent resin body 17. Then, a portion extending in the Y direction in the dicing region D passes through the opening 23a of the lead frame sheet 23 to form the extending portions 11d, 11e, 12d and 12e on the lead frames 11 and 12. The extending portions 11b and 11c are formed on the lead frame 11 by dividing the bridge 23b and the extending portions 12band 12c are formed on the lead frame 12 by dividing the bridge 23c. The front end surfaces of the extending portions lib to lie and 12b to 12e are exposed on the side surfaces of the transparent resin body 17.

Next, as shown in FIG. 3, various tests of the LED package 1 are performed. At this time, the front end surfaces of the extending portions lib to lie and 12b to 12e can be used as test terminals.

Next, effects of the embodiment will be described. In the LED package 1 according to the embodiment, the envelope is not made of white resin, the envelope never deteriorates due to absorption of light and heat that are generated from the LED chip 14. Especially when the envelope is made of polyamide-based thermoplastic resin, deterioration is easy to develop. However, there is no possibility that such deterioration occurs in the embodiment. For this reason, the LED package 1 according to the embodiment has a high durability. Therefore, the LED package 1 according to the embodiment has a long life and a high reliability and can be applied to a wide range of applications.

Further, in the LED package 1 according to the embodiment, the transparent resin body 17 is made of silicone resin. Since silicone resin has a high resistance against light and heat, the durability of the LED package 1 is further improved.

However, in the LED package 1, since the envelope is not provided, the transparent resin body 17 is not restricted by the envelope. For this reason, when the transparent resin body 17 is heated or cooled by light-on or light-off of the LED chip 14, heat deformation of the transparent resin body 17 is large. Further, since the transparent resin body 17 is made of relatively soft silicone resin, when the transparent resin body 17 is thermally deformed, the wires 15 and 16 can relatively move in the transparent resin body 17 while cutting the transparent resin body 17 and be deformed.

Then, in the embodiment, the wires 15 and 16 each are drawn from the terminal of the LED chip 14 once in the horizontal direction, and then, is curved so as to be convex downward and is connected to the lead frame. Thereby, a loop of each wire is formed to be low so that the wire is disposed in the lower portion of the transparent resin body 17. As a result, even if the transparent resin body 17 thermally expands and contracts in a repeated manner, displacement of the wires can be suppressed to be small. Moreover, since the transparent resin body 17 itself can be made thin, thermal stress generated in the transparent resin body 17 can be reduced. This can prevent the wires and bonding portions of wires from breaking due to the thermal stress, thereby improving reliability of the LED package 1.

This effect will be described below in more detail.

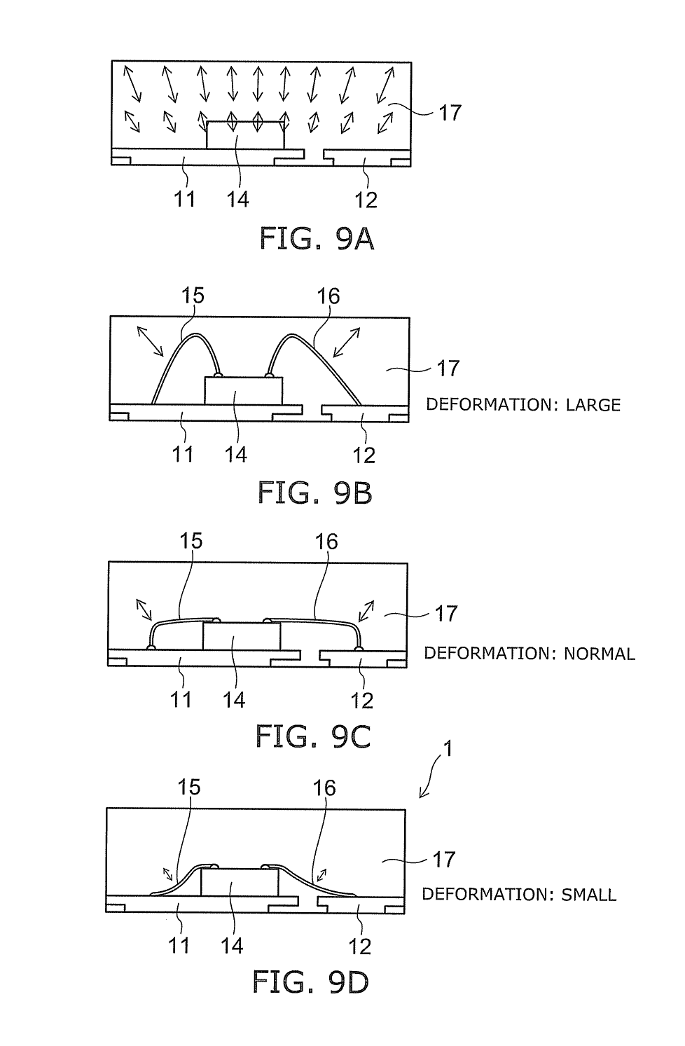

FIGS. 9A to 9D are schematic views illustrating the effect of the looped shape of the wires on wire deformation volume, FIG. 9A is a view showing thermal deformation of the transparent resin body, FIG. 9B is a view showing the case where the wires are drawn upwards from the LED chip, FIG. 9C is a view showing the case where the wires are drawn from the LED chip in the horizontal direction and then, are curved so as to be convex upward and FIG. 9D is a view showing the case where the wires are drawn from the LED chip in the horizontal direction and then, are curved so as to be convex downward.

In FIG. 9A, the wire is not shown.

As shown in FIG. 9A, since the lower portion of the transparent resin body 17 is restricted by the lead frames 11 and 12 and the upper surface and the side surfaces of the transparent resin body 17 are not restricted, when a heat cycle is applied to the transparent resin body 17, each point of the transparent resin body 17 reciprocates substantially outside upwards and inside downwards. Heat deformation of the upper portion of the transparent resin body 17 is larger than that of the lower portion and heat deformation of the peripheral portion is larger than that of the central portion.

For this reason, as shown in FIG. 9B, when the wires 15 and 16 are drawn from the LED chip 14 upwards so that the loops of the wire are high, intermediate portions of the loops are located in the upper portion of the transparent resin body 17 and therefore, displacement becomes large. As a result, when the transparent resin body 17 thermally expands and contracts in a repeated manner, the wires are also subjected to large deformation repeatedly and lead to fatigue breakdown relatively early. Further, the wires relatively move in the transparent resin body 17 while gradually cutting the transparent resin body 17, thereby greatly deforming their looped shape.

On the contrary, as shown in FIG. 9C, when the wires are drawn from the LED chip in the horizontal direction so that the loops of the wire are low, the whole of the wires are located in the lower portion of the transparent resin body 17 and therefore, displacement becomes small. As compared to the case shown in FIG. 9B, the wires are harder to be broken.

Further, as shown in FIG. 9D, the wires are drawn from the LED chip in the horizontal direction and then, are curved so as to be convex downward, as compared to the case shown in FIG. 9C, the intermediate portions of the wires are located at lower portions and therefore, the wire deformation volume becomes much smaller. Thus, the wires are much harder to be broken. In the embodiment, the wires 15 and 16 are shaped as shown in FIG. 9D, the wires are hard to be broken, resulting in a high reliability.

### TEST EXAMPLE 1

A test example 1 demonstrating this effect will be described below.

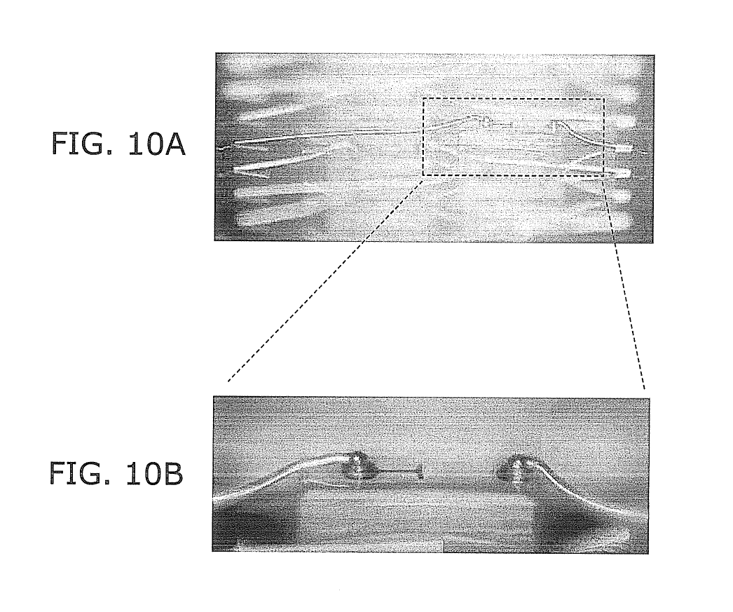

FIGS. 10A and 10B are optical microscope photographs showing a sample in the test example 1 and FIG. 10B shows the inside of a frame represented by a broken line in FIG. 10A.

FIGS. 10A and 10B show the samples having a looped shape (convex downward loop) as shown in FIG. 9D.

In the test example, four types of samples (10 samples per one type) were prepared. That is, two types of resin forming the transparent resin body and two types of looped shape of the wires were combined to form four types of combinations. The two types of resin forming the transparent resin body 17 was phosphor-containing silicone resin (hereinafter referred to as “phosphor-containing”) and filler-containing silicone resin (hereinafter referred to as “filler-containing”). The thickness of the whole LED package was set to 650 μm. One type of the looped shape was looped shape obtained by drawing the wires from the terminal of the LED chip in the horizontal direction and then, curving them to be convex downward as shown in FIG. 9D, FIG. 10A and FIG. 10B (hereinafter referred to as “convex downward loop”). The other type of the looped shape was looped shape obtained by drawing the wires from the terminal of the LED chip in the horizontal direction and then, curving them to be convex upward as shown in FIG. 9C (hereinafter referred to as “convex upward loop”). The loops of the wires were linearly formed when viewed from above (in the +Z direction).

These samples were subjected to a heat cycle test with a lowest temperature of −40° C. and a highest temperature of 110° C. Then, in some cycles, it was checked whether or not the LED chips were lighted and the number of unlighted samples was recorded. Table 1 shows results. For example, “ 1/10” in Table 1 indicates that one of 10 samples were unlighted.

TABLE 1

| | | | The number of heat cycles | | | | |
|---|---|---|---|---|---|---|---|
| No | Resin | Loop shape | 300 | 500 | 800 | 1115 | 1415 |
| 1 | Phosphor- | Convex | 0/10 | 0/10 | 0/10 | 0/10 | 0/10 |
| | containing | downward loop | | | | | |
| 2 | Phosphor- | Convex | 0/10 | 0/10 | 1/10 | 4/10 | 10/10 |
| | containing | upward loop | | | | | |
| 3 | Filler- | Convex | 0/10 | 0/10 | 0/10 | 0/10 | 0/10 |
| | containing | downward loop | | | | | |
| 4 | Filler- | Convex | 0/10 | 0/10 | 0/10 | 1/10 | 4/10 |
| | containing | upward loop | | | | | |

As shown in Table 1, when the transparent resin body was made of phosphor-containing silicone resin, in the “convex upward loop”, one sample was unlighted in 800 cycles and all of 10 samples were unlighted in 1415 cycles, while in the “convex downward loop”, all of 10 samples were normally lighted even after a lapse of 1415 cycles. When the transparent resin body is made of filler-containing silicone resin, in the “convex upward loop”, one sample was unlighted in 1115 cycles and four samples were unlighted in 1415 cycles, while in the “convex downward loop”, all of 10 samples were normally lighted even after a lapse of 1415 cycles. Therefore, the samples of “convex downward loop” were superior to the samples of “convex upward loop” in durability against the heat cycle.

Effects other than the above-mentioned effect in the embodiment will be described below.

In the LED package 1 according to the embodiment, by covering part of the lower surfaces and most of the end surfaces of the lead frames 11 and 12 with the transparent resin body 17, the peripheral part of the lead frames 11 and 12 is held. For this reason, the lower surfaces of the protruding portions 11g and 12g of the lead frames 11 and 12 can be exposed from the transparent resin body 17 to form the external electrode pad and at the same time, holding performance of the lead frames 11 and 12 can be improved. That is, by forming the protruding portions 11g and 12g at the center of the lead frames 11 and 12 in the X direction, notches are obtained at both ends of the lower surfaces of the lead frames 11 and 12 in the X direction. Then, since the transparent resin body 17 is turned into the notches, the lead frames 11 and 12 can be rigidly held. Thus, the lead frames 11 and 12 are hard to be peeled off from the transparent resin body 17 at dicing and therefore, yields of the LED package 1 can be increased. Moreover, in use of the manufactured LED package 1, the lead frames 11 and 12 can be prevented from being peeled off from the transparent resin body 17 due to temperature stress.

In the embodiment, many, for example, a few thousands of LED packages 1 can be made from one conductive sheet 21 collectively. This can reduce manufacturing costs per LED package 1. Moreover, since the envelope is not provided, the number of parts and processes is small and thus, costs are low.

Further, in the embodiment, the lead frame sheet 23 is formed by wet-etching. For this reason, when an LED package with new layout is manufactured, a mask original plate only needs to be prepared, and as compared to the case where the lead frame sheet 23 is formed by pressing by use of a mold or similar methods, initial costs can be reduced.

Furthermore, in the LED package 1 according to the embodiment, extending portions extend from each of the bases 11a and 12a of the lead frames 11 and 12. Thus, the bases themselves can be prevented from being exposed on the side surfaces of the transparent resin body 17, thereby enabling reduction of the exposed area of the lead frames 11 and 12. Further, the contact area of the lead frames 11 and 12 and the transparent resin body 17 can be increased. As a result, it is possible to prevent the lead frames 11 and 12 from being peeled off from the transparent resin body 17. In addition, corrosion of the lead frames 11 and 12 can be also suppressed.

When considering this effect in terms of the manufacturing method, as shown in FIG. 7B, by forming the opening 23a and the bridges 23b and 23c so as to interfere with the dicing region D in the lead frame sheet 23, the metal part that interferes with the dicing region D is reduced. Thus, dicing becomes easy and wear of the dicing blade can be suppressed. Further, in the embodiment, the four extending portions extend from each of the lead frames 11 and 12 in three directions. Thereby, in the mounting process of the LED chip 14 as shown in FIG. 4C, since the lead frame 11 is reliably supported by the lead frames 11 and 12 in the adjacent element region P in three directions, the mounting performance is high. Similarly, also in the wire bonding process as shown in FIG. 4D, the wire bonding positions are reliably supported in three directions, for example, ultrasonic wave applied at ultrasonic bonding hardly escapes and therefore, the wires can be excellently bonded to the lead frames and the LED chip.

Furthermore, in the embodiment, in the dicing process shown in FIG. 6B, dicing is performed from the side of the lead frame sheet 23. Thus, metal materials forming the cut end parts of the lead frames 11 and 12 extend on the side surface of the transparent resin body 17 in the +Z direction. For this reason, there never occurs the case where the metal materials extend on the side surface of the transparent resin body 17 in the −Z direction and protrude from the lower surface of the LED package 1, generating a burr. Therefore, when the LED package 1 is implemented, defective implementation due to the burr cannot occur.

Next, a variation the first embodiment will be described.

The variation is a variation of the method for forming the lead frame sheet.

That is, the variation is different from the above-mentioned first embodiment in the method for forming the lead frame sheet as shown in FIG. 4A.

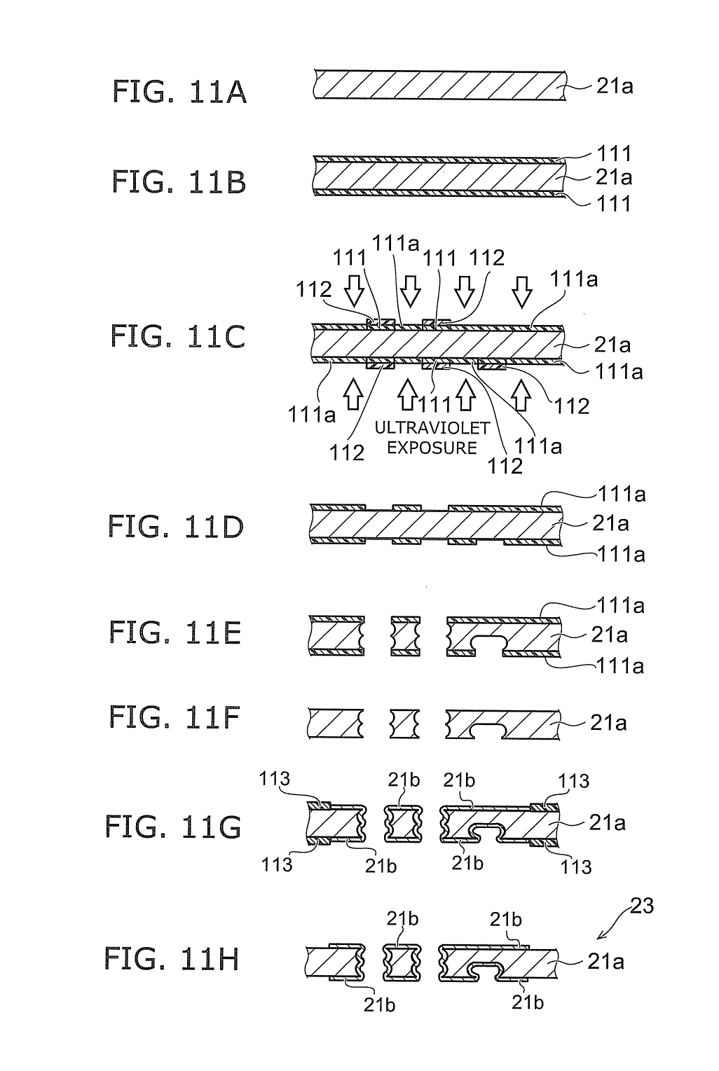

FIGS. 11A to 11H are process cross-sectional views illustrating the method for forming the lead frame in the variation

First, as shown in FIG. 11A, the copper plate 21a is prepared and cleaned. Next, as shown in FIG. 11B, resist coating is applied to both surfaces of the copper plate 21a and then, the copper plate 21a is dried to form a resist film 111. Next, as shown in FIG. 11C, a mask pattern 112 is disposed on the resist film 111, is irradiated with ultraviolet light and exposed. Thereby, an exposed part of the resist film 111 is cured to form a resist mask 111a. Next, as shown in FIG. 11D, development is performed and an uncured part of the resist film 111 is washed off. Thereby, a resist pattern 111a remains on the upper and lower surfaces of the copper plate 21a. Next, as shown in FIG. 11(e), etching is performed using the resist pattern 111a as a mask to remove the exposed part of the copper plate 21a from the both surfaces. At this time, etching depth is set to about a half of the thickness of the copper plate 21a. Thus, a region etched from one surface is half-etched and a region etched from both surfaces is penetrated. Next, as shown in FIG. 11(f), the resist pattern 111a is removed. Next, as shown in FIG. 11(g), an end part of the copper plate 21a is covered with a mask 113 and plated. Thereby, the silver plating layer 21b is formed on the copper plate 21 except for the end part. Next, as shown in FIG. 11H, the mask 113 is removed by washing. After that, an inspection is performed. In this manner, the lead frame sheet 23 is prepared. Other structures, manufacturing method and effects in the modification example are the same as those in the above-mentioned first embodiment.

Next, a second embodiment will be described.

The embodiment is different from the above-mentioned first embodiment in the looped shape of the wires.

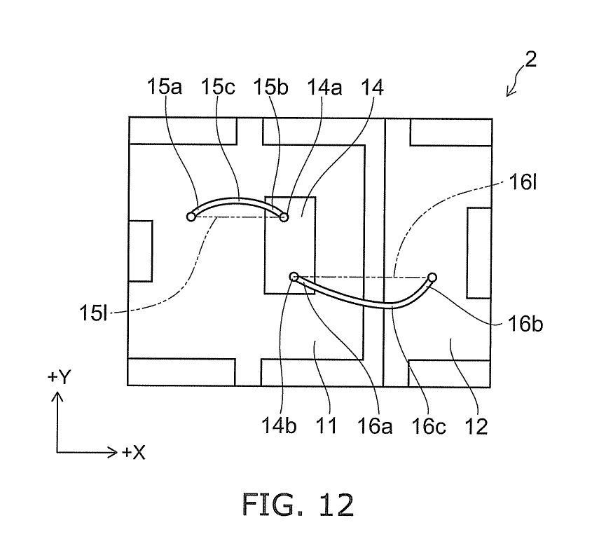

FIG. 12 is a plan view illustrating an LED package according to the embodiment.

As shown in FIG. 12, in the LED package according to the second embodiment, an intermediate part 15c of the wire 15 other than the both ends 15a and 15b is disposed at a position that falls outside a region directly above a straight line 151 connecting the end 15a to the end 15b of the wire 15. Similarly, an intermediate part 16c of the wire 16 other than the both ends 16a and 16b is disposed at a position that falls outside a region directly above a straight line 161. As described above, in the embodiment, the wires 15 and 16 each make a detour in the Y direction to have a slack in the Y direction.

In the embodiment, since the wires 15 and 16 each have a slack in the Y direction, thermal stress applied from the transparent resin body 17 to the wires 15 and 16 can be relieved. This can prevent breakage of the wires 15 and 16 more reliably.

Next, a third embodiment will be described.

The embodiment is an example of the wire looped shape in the case where a plurality of LED chips is mounted on one LED package.

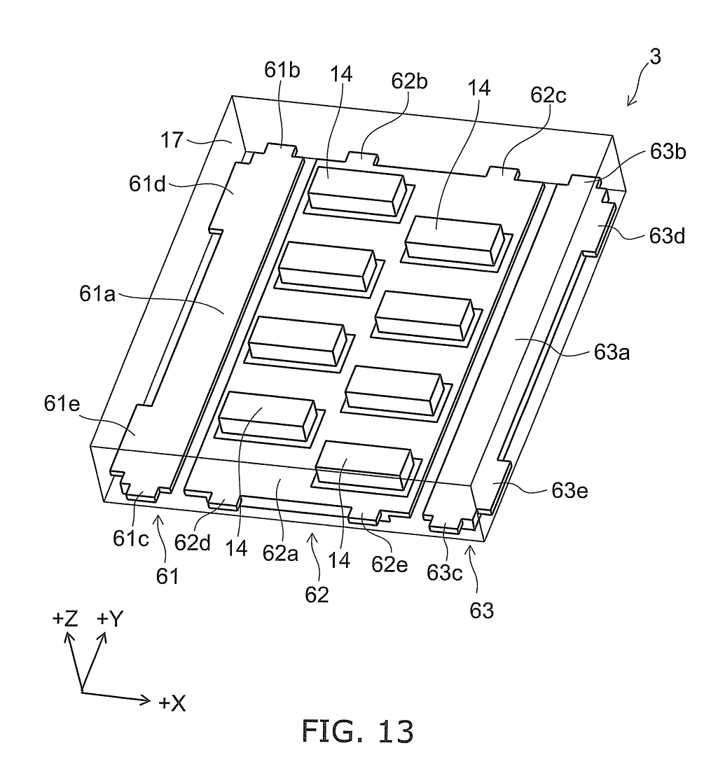

FIG. 13 is a perspective view illustrating an LED package according to the embodiment,

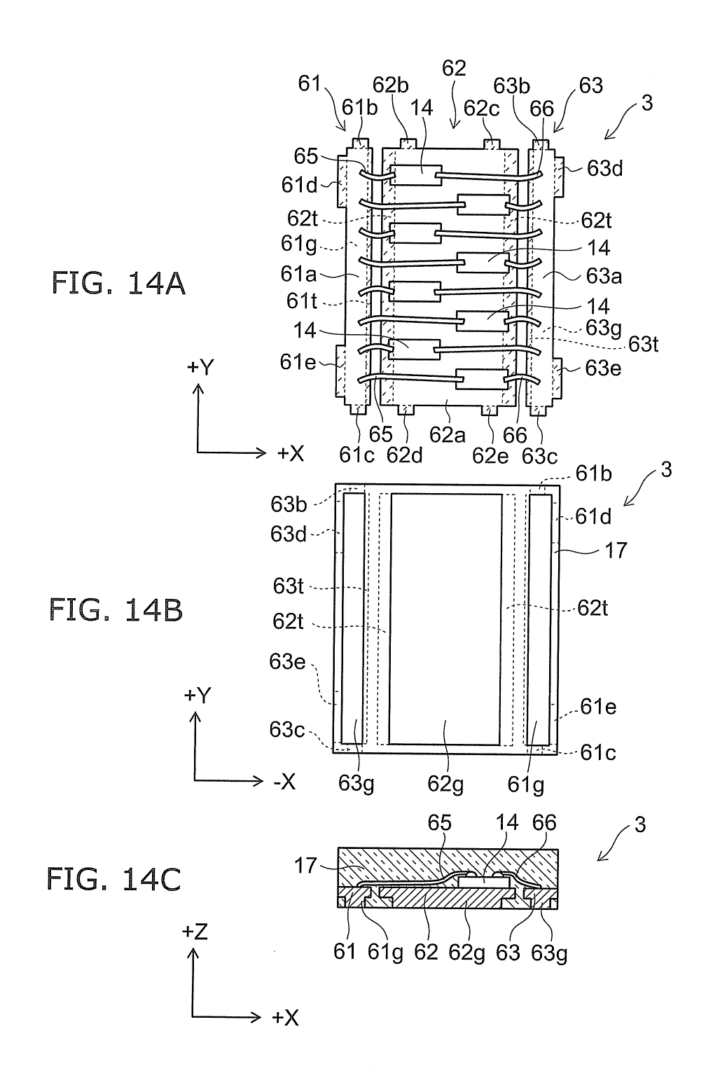

FIG. 14A is a plan view illustrating lead frames, LED chips and wires of the LED package according to the embodiment, FIG. 14B is a bottom view illustrating the LED package and the FIG. 14C is a cross-sectional view illustrating the LED package,

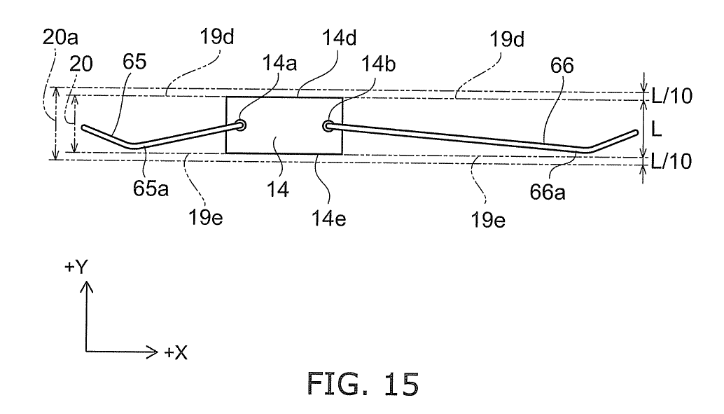

FIG. 15 is a plan view illustrating the LED chips and wires of the LED package according to the embodiment.

FIG. 13 does not show the wires.

As shown in FIG. 13 and FIG. 14, in an LED package 3 according to the embodiment, three lead frames 61, 62 and 63 are provided separately from one another. In the lead frame 61, from a strip-like base 61a having the longitudinal direction as the Y direction, a extending portion 61b extends in the +Y direction, a extending portion 61c extends in the −Y direction and two extending portions 61d and 61e extend in the −X direction. In the lead frame 62, from a strip-like base 62a having the longitudinal direction as the Y direction, two extending portions 62b and 62c extend in the +Y direction and two extending portions 62d and 62e extend in the −Y direction. Although the shape of the lead frame 63 is the shape obtained by inverting the lead frame 61 in the X direction, the extending portions 63d and 63e are narrower than the extending portions 61d and 61e.

In the LED package 3, a plurality of, for example, eight LED chips 14 are provided. The LED chips 14 are arranged in two rows in the Y direction and four LED chips 14 are aligned in one row. The row in the +X direction is shifted from the row in the −X direction by half cycle in a staggered configuration. Each of the LED chips 14 is mounted on the lead frame 62 via a die-mount material (not shown) so that a direction going from one terminal toward the other terminal is the X direction. The terminal 14a of each LED chip 14 (refer to FIG. 15) is connected to the lead frame 61 via a wire 65 and the terminal 14b (refer to FIG. 15) is connected to the lead frame 63 via a wire 66. Further, lower surfaces of protruding portions 61g, 62g and 63g of the lead frames 61, 62 and 63 are exposed on the lower surface of the transparent resin body 17. On the contrary, lower surfaces of thin plate portions 61t, 62t and 63t of the lead frames 61, 62 and 63 are covered with the transparent resin body 17. In FIG. 14A, relatively thin portions in the lead frame 61, 62 and 63, that is, each thin plate portion and each extending portion are hatched by broken lines.

As in the above-mentioned first embodiment, the wires 65 and 66 are curved so as to be convex downward. The intermediate portion of each wire is disposed at a position that falls outside a region directly above a straight line connecting both ends of the wire to each other. The intermediate portion of each wire is displaced in a direction toward the center of the transparent resin body 17 in the Y direction with respect to the region directly above the straight line connecting the both ends of the wire. That is, in the LED package 3, when viewed from above (in the +Z direction), the intermediate portions of the wires 65 and 66 connected to the four LED chips 14 on the +Y direction side are displaced in the −Y direction with respect to the straight line connecting the both ends of the wire. When viewed from above (in the +Z direction), the intermediate portions of the wires 65 and 66 connected to the four LED chips 14 on the −Y direction side are displaced in the +Y direction with respect to the straight line connecting the both ends of the wire. In this manner, each wire is curved toward the inside of the LED package 3. Hereinafter, such wire looped shape is referred to as “inwardly curved”. On the contrary, the state where the wires are curved toward the outside of the LED package is referred to as “outwardly curved”. The state where the intermediate portion of each wire is located at a region directly above the straight line connecting the both ends of the wire is referred to as “linear”.

As shown in FIG. 15, a preferable scope of displacement of the wires has an upper limit. That is, when viewed from above, it is preferred that the intermediate portions 65a and 66a of the wires 65 and 66 are located in a region 20 sandwiched between extension surfaces 19d and 19e, which extend in the X direction, of two side surfaces 14d and 14e of the LED chip 14 to which connected to the wires. However, since an error necessarily occurs in the bonding positions of the wires and the bonded wires are slightly deformed when molded with a resin material, even when it is attempted to locate the wires in the region 20 at bonding portion of the wires in the manufactured LED package may protrude from the region 20. In even such case, if most of the wires are located in the region 20, it is possible to obtain an effect that is almost equal to the effect obtained in the case where the whole of the wires are located in the region 20. Thus, in the embodiment, given that a distance between the extension surface 19d and the extension surface 19e is L, a region 20a extended outwards from the extension surfaces of 20a by (L/10) is set. And, even when part of each wire protrudes from the region 20, if the wire is located in the region 20a, the wire is regarded to be located in the region 20. (L/10) as the displacement, that is, 10% of the width of the LED chip, is a length of about a thickness of the wire.

In the embodiment, by inwardly curving the wire, as compared to the case where the wire is linear or outwardly curved, breakage of the wire due to thermal stress can be prevented more reliably.

This effect will be specifically described below based on a test example 2.

### TEST EXAMPLE 2

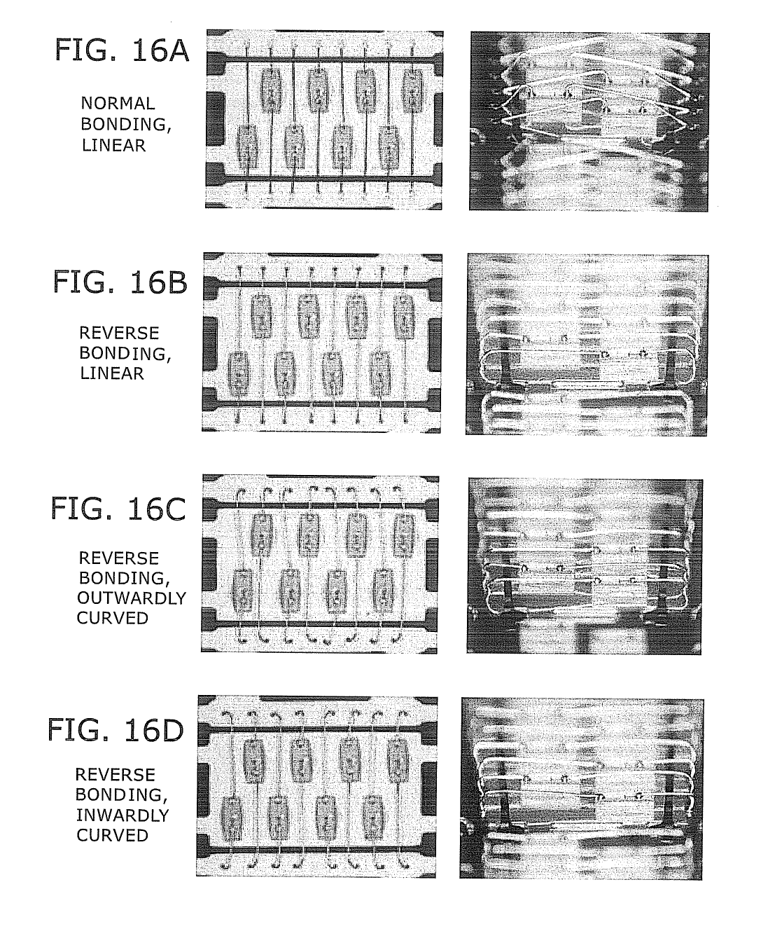

FIGS. 16A to 16D are photographs illustrating samples in the test example 2,

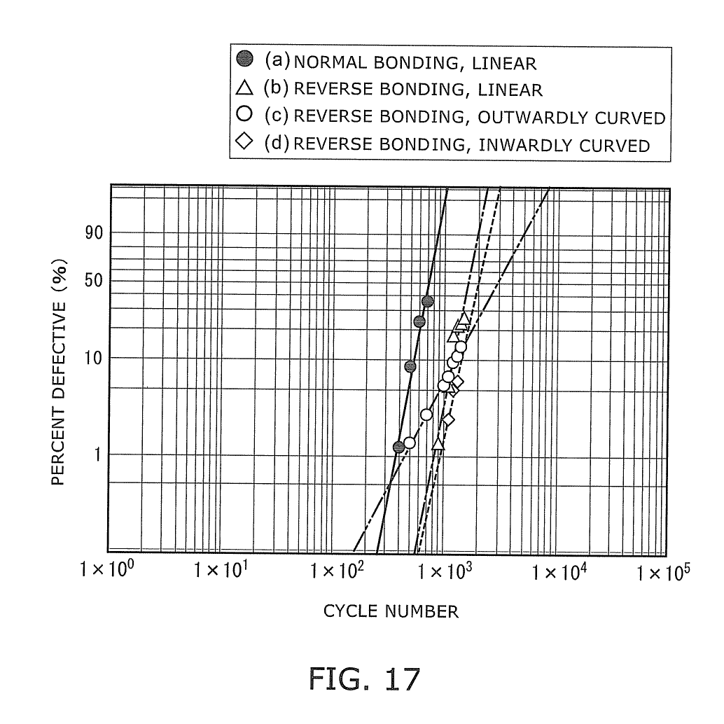

FIG. 17 is a graph illustrating the effect of the wire looped shape on durability, and its horizontal axis represents the number of cycles and its vertical axis represents a percent defective.

As shown in FIGS. 16A to 16D, in the test example, eight LED chips were mounted on the lead frames and wires were bonded between the LED chips and the lead frames to prepare test samples. However, unlike the above-mentioned third embodiment, the wires were curved so as to be convex upward.

In the sample shown in FIG. 16A, as shown in FIG. 9B, the wires were drawn from the LED chips 14 substantially upwards (in the +Z direction) so that a chip-side drawing angle was greater than a frame-side drawing angle. Here, the “chip-side drawing angle” refers to an angle that the upper surface (XY plane) of the LED chip 14 forms with the direction of drawing the wire 15 from the terminal 14a and the “frame-side drawing angle” refers to an angle that the upper surface 12h (XY plane) of the lead frame 12 with the direction of drawing the wire 15 from the lead frame 12. Hereinafter, such wire state is referred to as “normal bonding”. Specifically, the chip-side drawing angle was set to 80 degrees and the frame-side drawing angle was set to 20 degrees. The wires were shaped to be “linear”. That is, the sample shown in FIG. 16A is a sample with “normal bonding” and “linear” wires.

In the sample shown in FIG. 16B, as shown in FIG. 9C, the wires were drawn from the LED chip 14 in the horizontal direction (substantially in the X direction) so that the chip-side drawing angle was smaller than the frame-side drawing angle. Hereinafter, such wire state is referred to as “reverse bonding”. Specifically, the chip-side drawing angle was set to 0 degree and the frame-side drawing angle was set to 90 degree. The wires were shaped to be “linear”. That is, the sample shown in FIG. 16B is a sample with “reverse bonding” and “linear” wires.

In the sample shown in FIG. 16C, the chip-side drawing angle and the frame-side drawing angle were the same as those in the sample shown in FIG. 16B. The wires were shaped to be “outwardly curved”. That is, the sample shown in FIG. 16C is a sample with “reverse bonding” and “outwardly curved” wires.

In the sample shown in FIG. 16D, the chip-side drawing angle and the frame-side drawing angle were the same as those in the sample shown in FIG. 16B. The wires were shaped to be “inwardly curved”. That is, the sample shown in FIG. 16D is a sample with “reverse bonding” and “inwardly curved” wires. In this sample, when viewed from above, the intermediate part of each wire was located in a region sandwiched between extension surfaces, which extended in the X direction, of two side surfaces of the LED chip to which the wire was connected.

These samples were subjected to a heat cycle test with a lowest temperature of −40° C. and a highest temperature of 110° C. Then, in some cycles, it was checked whether or not the LED chips were lighted and the proportion of the unlighted LED chips was defined as a percent defective. Test results are shown in FIG. 17. Based on the test results shown in FIG. 17, the number of cycles having the percent defective of 1% was estimated. The number of heat cycles is defined as “life”. Results are shown in Table 1. “Improvement rate” in Table 2 is a value obtained by standardizing the life using the test results of the sample with “positively bonded” and “linear” wires as a comparative example as a reference.

TABLE 2

| | Wire drawing | | Life | Improvement |
|---|---|---|---|---|
| Sample | direction | Loop shape | (cycle number) | rate |
| (a) | Normal | Linear | 373 | 1 |
| | bonding | | | |
| (b) | Reverse | Linear | 823 | 2.2 |
| | bonding | | | |
| (c) | Reverse | Outwardly | 446 | 1.2 |
| | bonding | curved | | |
| (d) | Reverse | Inwardly | 924 | 2.5 |
| | bonding | curved | | |

As shown in FIG. 17 and Table 2, as compared to the sample with “normal bonding” wires in FIG. 16A, the sample with “reverse bonding” wires improved its life by about 2.2 times. When comparing the samples with reversely bonded wires with each other, the sample with “inwardly curved” wires in FIG. 16D further improved its life than the sample with “linear” wires in FIG. 16B. The life of the sample with “outwardly curved” wires in FIG. 16C was longer than that of the sample with “normal bonding” and “linear” wires in FIG. 16A, but was shorter than the sample with “reverse bonding” and “linear” wires in FIG. 16B.

The reason why the life of the sample with “inwardly curved” wires is longer than that of the sample with “outwardly curved” wires can be assumed as follows. That is, as described with reference to FIG. 9A, when the transparent resin body is heated and expands, a force going toward the outside upward of the LED package is applied to the wire, and when the transparent resin body is cooled and contracts, a force going toward the inside downward of the LED package is applied to the wire. Thus, the intermediate part of the wire substantially reciprocates between the outside upward and the inside downward. When the wire is shaped to be “inwardly curved”, since the intermediate part of the wire is located inside upwards with respect to both ends, the above-mentioned reciprocating motion acts to rotate the wire loop about the straight line connecting the both ends of the wire to each other. For this reason, allowance of the reciprocating motion is high. On the other hand, when the wire is shaped to be “outwardly curved”, since the intermediate part of the wire is located outside upwards with respect to both ends, the above-mentioned reciprocating motion acts to crush or pull out the wire loop. For this reason, allowance of the reciprocating motion is low. For such reason, it can be deemed that the life of the sample with “inwardly curved” wires is longer than that of the sample with “outwardly curved” wires and the life of the sample with “linear” wires is a middle therebetween.

### TEST EXAMPLE 3

The test example is a test example that estimates magnitude of curve of the wire on the life of the LED package. 10 samples with “reverse bonding” and “inwardly curved” wires were prepared. In these samples, as described in the above-mentioned third embodiment, when viewed from above, the intermediate part of each wire was located in a region sandwiched between extension surfaces, which extended in the X direction, of two side surfaces of the LED chip to which the wire was connected. As described above, an error within 10% was allowed. Such curve extent was expressed as “normal”. The thickness of the transparent resin body in these samples was set to 650 μm. In addition to the above-mentioned 10 samples, 10 samples in which “reverse bonding” and “inwardly curved” wires were used and the curve extent of the wires was large was prepared. In these samples, unlike the third embodiment, when viewed from above, the intermediate part of each wire was extended to the outside of the region sandwiched between extension surfaces, which extended in the X direction, of two side surfaces of the LED chip to which the wire was connected. That is, the intermediate part was extended to the outside of the enlarged region 20a shown in FIG. 15. Such curve extent was expressed as “large”. The thickness of the transparent resin body in these samples was set to 650 μm.

These 20 samples were subjected to a heat cycle test with a lowest temperature of −40° C. and a highest temperature of 110° C. Then, it was checked whether or not the LED chips were lighted each 100 cycles and the number of unlighted LED chip was recorded. Results are shown in Table 3. Notation of Table 3 is the same as that of Table 1.

TABLE 3

| | | Curve | The number of heat cycles | | | | |
|---|---|---|---|---|---|---|---|
| No. | Resin | extent | 300 | 500 | 800 | 1115 | 1415 |
| 5 | Phosphor- | Normal | 0/10 | 0/10 | 0/10 | 0/10 | 8/10 |
| | containing | | | | | | |
| 6 | Phosphor- | Large | 0/10 | 4/10 | 8/10 | 5/10 | 10/10 |
| | containing | | | | | | |
| 7 | Filler- | Normal | 0/10 | 0/10 | 0/10 | 0/10 | 0/10 |
| | containing | | | | | | |
| 8 | Filler- | Large | 1/10 | 1/10 | 7/10 | 10/10 | 10/10 |
| | containing | | | | | | |

In the samples with “normal” curve extent, no unlighted sample occurred by the end of 1115 cycles. On the contrary, in the samples with “large” curve extent, one of 20 samples was unlighted at the end of 300 cycles. Although the unlighted sample had practically acceptable durability, it was inferior to the samples with “normal” curve extent in durability against heat cycle.

Although some embodiments of the invention have been described, these embodiments are presented merely as examples and are not intended to limit the scope of the invention. These new embodiments can be implemented in other various modes and variously omitted, replaced and changed so as not to deviate from the subject matter of the invention. These embodiments and their modifications are included in the scope and the subject matter of the invention as well as in the invention stated in claims and its equivalents.

For example, in the above-mentioned first embodiment, the lead frame sheet 23 is formed by wet-etching, and however, the invention is not limited to this, and the lead frame sheet 23 may be formed by mechanical means such as pressing. Further, in the above-mentioned first embodiment, in the lead frame, the silver plating layer is formed on the upper and lower surfaces of the copper plate, and however, the invention is not limited to this. For example, the silver plating layer may be formed on the upper and lower surfaces of the copper plate and a rhodium (Rh) plating layer may be formed on at least one of the silver plating layers. A copper (Cu) plating layer may be formed between the copper plate and the silver plating layer. A nickel (Ni) plating layer may be formed on the upper and lower surfaces of the copper plate and a gold-silver alloy (Au—Ag alloy) plating layer may be formed on the nickel (Ni) plating layer.

In each of the above-mentioned embodiments and their modification examples, the LED chip emits blue light, the phosphors absorb blue light and emit yellow light and the color of light emitted from the LED package is white, and however, the invention is not limited to this. The LED chip may emit visible light other than blue light and may also emit ultraviolet light or infrared light. The phosphors are not limited to the phosphors that emit yellow light and may be phosphors that emit blue light, green light or red light, for example. Further, LED package need not have the phosphors. In this case, light emitted from the LED chip is emitted from the LED package.

Further, in each of the above-mentioned embodiments and their modification examples, the shape of the base of the lead frame is rectangular when viewed from above, and however, the shape of the base may be shaped so that at least one corner is cut. Thereby, since the corner having a right angle or a sharp angle is removed in the vicinity of the corner of the LED package, these corners do not contribute to resin peeling or crack. As a result, occurrence of resin peeling or crack in the whole of the LED package can be suppressed.

In the above-mentioned embodiments, a LED package having a high durability can be realized at low costs.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An LED package comprising:
a first and a second lead frame separated from each other;
an LED chip provided above the first and second lead frames, the LED chip having a pair of terminals provided on an upper surface of the LED chip, one of the terminals being connected to the first lead frame and one other terminal being connected to the second lead frame;
a wire drawn out from the one terminal in a horizontal direction to connect the one terminal to the first lead frame;
a resin body covering the LED chip, the wire, an upper surface, a part of a lower surface and a part of an end surface of each of the first and second lead frames to expose a remaining part of the lower surface and a remaining part of the lower surface,
an outer shape of the resin body forming an outer shape of the LED package.

2. The package according to claim 1, wherein the wire is curved so as to be convex downward.

3. The package according to claim 1, wherein
a bump is formed at a bonding portion of the one terminal and the wire, and
the wire is not disposed above the bump.

4. The package according to claim 1, wherein
a part of the wire other than both ends of the wire is disposed at a position that falls outside of a region directly above a straight line connecting the both ends of the wire to each other.

5. The package according to claim 4, wherein
the part of the wire other than both ends of the wire is displaced in a direction toward a center of the resin body with respect to the region directly above the straight line.

6. The package according to claim 1, wherein
the resin body is formed from silicone resin.

7. The package according to claim 1, wherein
the first and the second lead frame are disposed on one plane,
at least one of the first lead frame and the second lead frame including
a base having an end surface covered with the resin body, and
three extending portions extending from the base in directions different from one another, and each of the three extending portions having a lower surface covered with the resin body and a front end surface of the three extending portions exposed on a side surface of the resin body, and
a protruding portion is formed in a region in one of a lower surface of the first lead frame and a lower surface of the second lead frame, the region being separated from one other region, a lower surface of the protruding portion is exposed on the lower surface of the resin body and a side surface of the protruding portion is covered with the resin body.

8. The package according to claim 7, wherein
when viewed from above, a shape of the base is rectangular, and
the three extending portions are disposed on one plane and extend from three sides different from one another of the base.

9. The package according to claim 1, further comprising another wire drawn from the one other terminal in a horizontal direction and connecting the one other terminal to the second lead frame.

10. The package according to claim 9, wherein
the another wire is curved so as to be convex downward.

11. The package according to claim 9, wherein
another bump is formed at a bonding portion of the one other terminal and the another wire, and
the another wire is not disposed above the bump.

12. The package according to claim 9, wherein
a part of the another wire other than both ends of the another wire is disposed at a position that falls outside of a region directly above a straight line connecting the both ends of the another wire to each other.

13. The package according to claim 12, wherein
the part of the another wire other than both ends of the another wire is displaced in a direction toward a center of the resin body with respect to the region directly above the straight line.

14. The package according to claim 1, wherein
the one terminal and the one other terminal are both provided on an upper surface of the LED chip,
a third lead frame is further provided which is disposed between the first lead frame and the second lead frame, a part of a lower surface and a part of an end surface of the third lead frame being exposed from the resin body, and
the LED chip is mounted on the third lead frame.

15. The package according to claim 1, wherein
the LED chip is provided in a plurality and the plurality of chips are arranged in a staggered manner.
